(19) United States
(12) Patent Application Publication
(10) Pub. No.: US 2013/0072056 A1
(43) Pub. Date: Mar. 21, 2013

(54) ISOLATION TOOL FOR TERMINALS OF ELECTRIC DISTRIBUTION METER ENCLOSURES

(71) Applicants: Antonio Vitucci, Wauconda, IL (US); Michael D. Berg, Carol Stream, IL (US)

(72) Inventors: Antonio Vitucci, Wauconda, IL (US); Michael D. Berg, Carol Stream, IL (US)

(21) Appl. No.: 13/238,369

(22) Filed: Sep. 21, 2011

(51) Int. Cl. H01R 31/08; H05K 13/00; H01B 17/14

(52) U.S. Cl. 439/508; 174/138 R; 29/592.1

(57) ABSTRACT

An electrical isolation tool (50, 80) and method are provided for isolating a pair (34) of spaced electric terminals (30, 32) in an electric distribution meter enclosure (10). The method involves gripping a portion (55, 84) of an isolation tool (50, 80) with a user's hand, inserting a portion (57, 86) of the isolation tool (50, 80) into an installed position between the enclosure (10) and the terminals (30, 32) while performing the gripping step, performing a service operation within the enclosure (10) while the isolation tool (50, 80) is in the installed position, and gripping a portion (55, 84) of the isolation tool (50, 80) with a user's hand after the performing step and removing the isolation tool (50, 80) from the installed position. The tool (50, 80) includes a one piece, unitary component (52, 82) having a grip portion (55, 84) and an electrical isolation portion (57, 86).

### CROSS-REFERENCE TO RELATED APPLICATIONS

Not Applicable.

### FEDERALLY SPONSORED RESEARCH OR DEVELOPMENT

Not Applicable.

MICROFICHE/COPYRIGHT REFERENCE

Not Applicable.

### FIELD

This application relates generally to electric distribution systems and methods, and more particularly to systems and methods for the installation and servicing of electric distribution meters and enclosures for such meters.

### BACKGROUND

Electric distribution meter enclosures typically include two spaced pairs of electric terminals, with one of the terminals of each pair (commonly called an input terminal) being connected to the power supply conduit from an electric utility and the other terminal of each pair (commonly called an output terminal) being connected to a supply conduit to a customer of the utility. Contractors who install new electric distribution meter enclosures often connect the input terminals from the electric utility directly to the output terminals to the customer supply conduit using a so-called “bypass conductor”. These bypass conductors are removed when the electric distribution meter is ready for installation, a function typically performed by the electric utility or a third party serving the electric utility. In some cases, the electric utility or third party bypasses the same terminals when service orders require doing so.

When the bypass conductors are installed or removed, a potentially hazardous condition exists. The bypass conductor can come into contact with the enclosure, which is connected to earth ground. If such contact occurs, electric energy can be discharged through the enclosure and create a hazardous condition. Technicians who install or remove these connections sometimes isolate the conductors and terminals from the enclosure. However, the tools or materials used for isolating the two conducting entities are not necessarily tested or certified to safety standards.

### SUMMARY

In accordance with one feature, an electrical isolation tool is provided for isolating a pair of spaced electric terminals in an electric distribution meter enclosure, the enclosure being electrically grounded, one of the terminals being connected to a power supply conduit from a utility, and the other of the terminals being connected to a customer supply conduit. The isolation tool includes a one piece, unitary component having a grip portion and an electrical isolation portion. The grip portion adapted to be grasped by a hand of a user for installation and removal of the isolation tool to and from the electric distribution meter enclosure. The electrical isolation portion is sized to extend continuously between the enclosure and the pair terminals with the isolation tool in an installed condition. The grip portion and the isolation portion include at least one layer of electrical insulation material extending continuously between the portions.

As one feature, the at least one layer of electrical insulation material is a flexible, resilient sheet deformable between an uninstalled condition and an installed condition.

In one feature, the sheet is planar in the uninstalled condition.

According to one feature, the sheet is deformed to fit between the enclosure and the pair of terminals and to be frictionally engaged with at least one of the enclosure and the pair of terminals with the isolation tool in the installed condition.

In one feature, the at least one layer of electrical insulation material is at least three layers of electrical insulation material, with two of the at least three layers being outer layers defining opposite faces of the sheet and the third of the at least three layers being an indicator layer located between the other two of the at least three layers and having a color selected to differentiate the indicator layer from the other two of the at least three layers.

According to one feature, the grip portion and the electrical isolation portion are interchangeable portions of the sheet.

As one feature, the sheet is rectangular in shape with sides having lengths in the range of 5 inches to 10 inches.

In one feature, the isolation portion is configured to withstand at least a 1,000 volt differential across the isolation portion.

According to one feature, the isolation tool further includes an electrical shorting conductor carried in the isolation portion and configured to extend between and engage with the terminals, and wherein the grip portion includes a handle extending from the isolation portion to be encircled by a user's hand.

In accordance with one feature, a method is provided for electrically isolating a pair of spaced electric terminals in an electric distribution meter enclosure, the enclosure being electrically grounded, one of the terminals being connected to a power supply conduit from a utility, and the other of the terminals being connected to a customer supply conduit. The method includes the steps of gripping a portion of an isolation tool with a user's hand, inserting a portion of the isolation tool into an installed position between the enclosure and the terminals while performing the gripping step, performing a service operation within the enclosure while the isolation tool is in the installed position, and gripping a portion of the isolation tool with a user's hand after the performing step and removing the isolation tool from the installed position.

As one feature, the first recited gripping step includes gripping a planar portion of a sheet defining the isolation tool, and the inserting step includes deforming a planar portion of the sheet defining the isolation tool.

In one feature, the inserting step includes engaging an electrical conduit member of the isolation tool with each of the terminals.

In accordance with one feature, a method is provided for electrically isolating pairs of spaced electric terminals in electric distribution meter enclosures, each of the enclosures being electrically grounded, one of the terminals of each pair being connected to a power supply conduit from a utility, and the other of the terminals of each pair being connected to a customer supply conduit. The method includes the steps of gripping a portion of an isolation tool with a user's hand, inserting a portion of the isolation tool into an installed position between an electric distribution meter enclosure and a pair of terminals while performing the gripping step, performing a service operation within the enclosure while the isolation tool is in the installed position, removing the isolation tool from the installed position after the performing step, and repeating the gripping, inserting, performing steps on a plurality of enclosures using the same isolation tool.

Other features and advantages will become apparent from a review of the entire specification, including the appended claims and drawings.

### BRIEF DESCRIPTION OF THE DRAWINGS

FIGS. 1A-1C are isometric views of an electric distribution meter enclosure, with FIG. 1A showing the enclosure having an electric distribution meter installed therein, FIG. 1B showing the enclosure with the meter removed, and FIG. 1C showing the enclosure with a front cover of the enclosure removed to expose the input terminals from the electrical utility and the output terminals to a customer premise;

FIG. 2 is an isometric view showing an isolation tool in an uninstalled condition, with arrows indicating the movement of the isolation tool during installation into the enclosure;

FIG. 3 is a front elevation of the enclosure showing the isolation tool of FIG. 2 in an installed condition;

FIG. 4 is a plan view of the isolation tool of FIGS. 2 and 3;

FIG. 5 is a side elevation of the isolation tool of FIGS. 2-4;

FIG. 6 is an enlarged view of the portion circled by line 6-6 in FIG. 5;

FIG. 7 is an isometric view showing another embodiment of an insulation tool in an uninstalled condition, with arrows indicating the movement of the isolation tool during installation into an enclosure;

FIG. 8 is a side elevation view of the tool of FIG. 7; and

FIG. 9 is a view taken from line 9-9 in FIG. 8.

### DETAILED DESCRIPTION

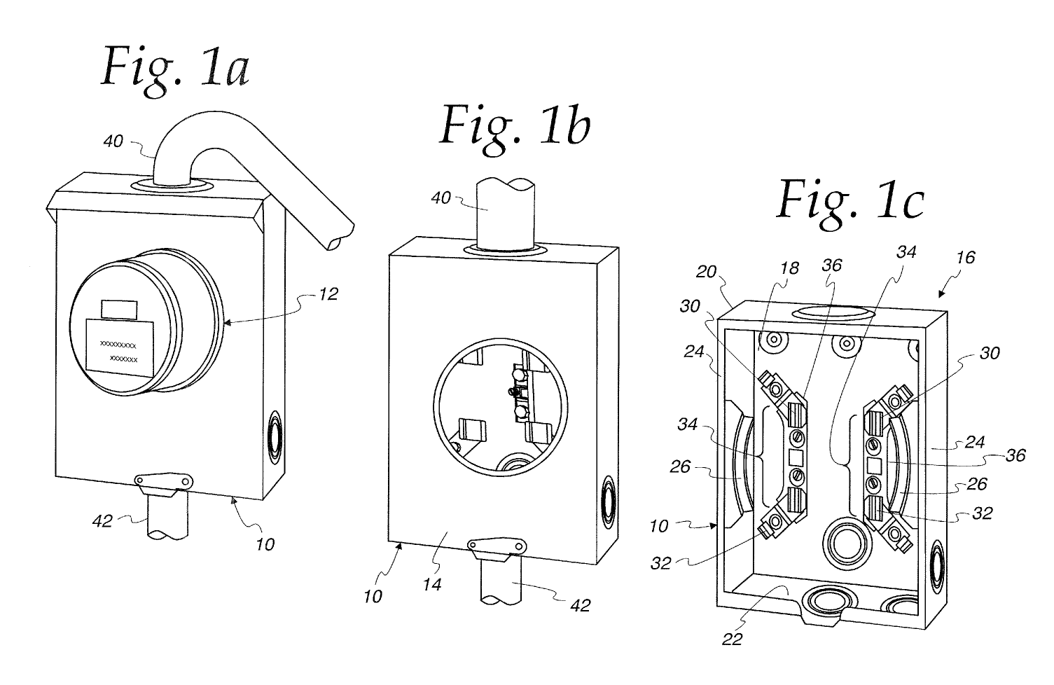

With reference to FIGS. 1A-1C, an electric distribution meter enclosure 10 is shown, with FIG. 1A showing the enclosure 10 having an electric distribution meter 12 mounted therein, FIG. 1B showing the enclosure 10 with the meter 12 removed, and FIG. 1C showing the enclosure 10 with a front cover 14 removed. As best seen in FIG. 1C the enclosure 10 includes a box shaped housing 16 having a back wall 18, an upper side wall 20, a lower side wall 22, and a pair of lateral side walls 24, with each of the lateral side walls 24 having a meter mount flange 26 extending laterally inwardly from an outer edge of the side wall 24. Two electrical input terminals 30 and two electrical output terminal 32 are provided within the enclosure 10 and are arranged in pairs 34 mounted on corresponding insulator blocks 36, with each pair including an input terminal 30 and an output terminal 32. The input terminals 30 are connected to a power supply conduit 40 (not shown in FIG. 1C) supplying electric power from an electric utility, and the output terminals 32 are connected to a customer supply conduit 42 (not shown in FIG. 1C) that supplies power to a customer's premises. The housing 16 of the enclosure 10 is connected to earth ground. As discussed in the background section, it is common for the input terminal 30 of each pair 34 to be electrically connected by a conductor to the output terminal 32 of the pair by installers and/or during servicing, and when such an electrical connection is removed, there is a danger that an arc will flash between the conductor and one of the lateral side walls 24 and/or one of the meter mount flanges 26.

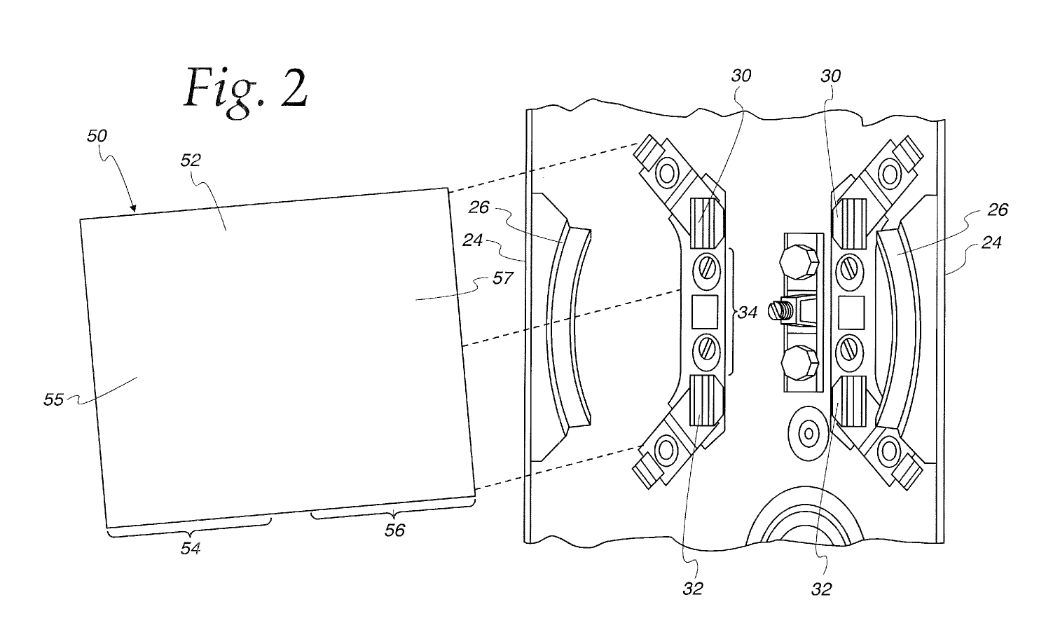

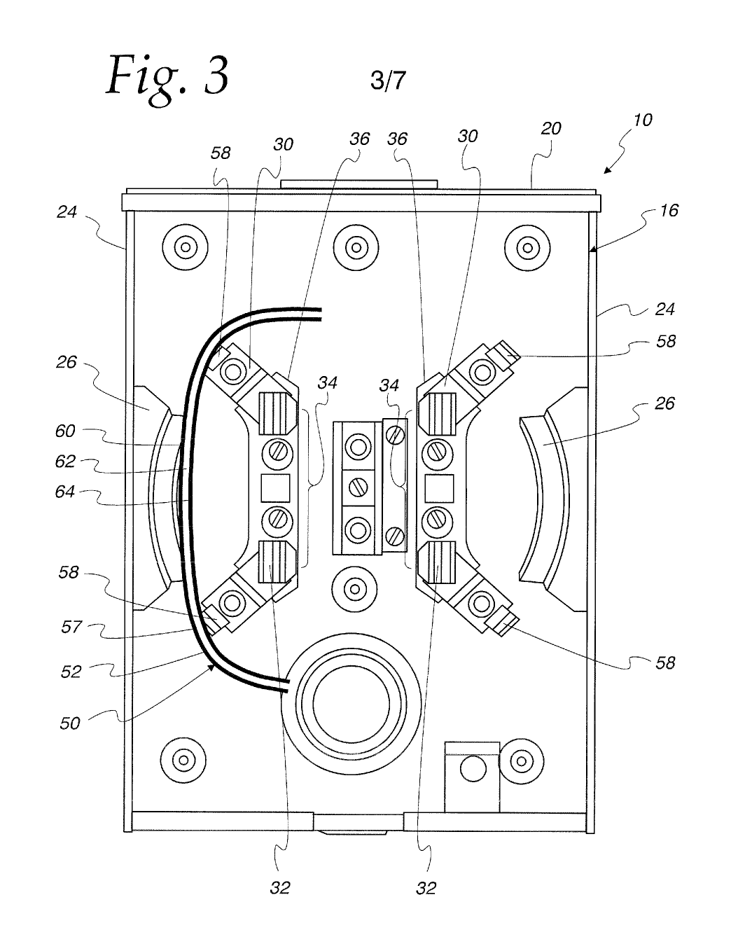

With reference to FIG. 2, an isolation tool 50 is shown and is defined by a flexible, resilient sheet 52 of suitable electrical insulation material. As best seen in FIGS. 2 and 4, the illustrated sheet 52 is planar in its uninstalled condition. An end portion 54 of the sheet 52 can serve as a grip portion 55 that can be grasped by a user's hand for installation and removal of the isolation tool 50. An opposite end portion 56 of the sheet 52 can serve as an insulation portion 57 that extends continuously between the enclosure 10 and a pair 34 of the terminals 30, 32 with the isolation tool 50 in an installed position, as shown in FIG. 3. In this regard, again as shown in FIG. 3, the sheet 52 has an installed condition wherein the sheet 52 is deformed to fit between the enclosure 10 (specifically one of the lateral side walls 24 and one of the mount flanges 26) and one pair 34 of the terminals 30, 32, with the sheet 52 being frictionally engaged with the enclosure 50 (specifically one of the mount flanges 26 in the illustrated example) and extended portions 58 of the terminals 30 and 32.

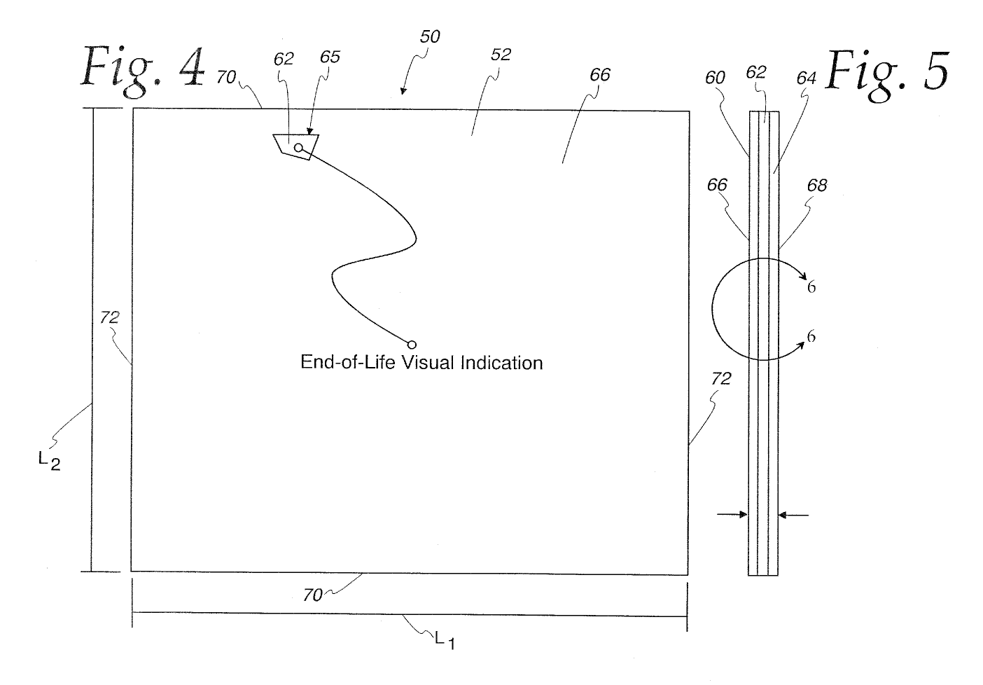

As best seen in FIG. 3-6, the sheet 52 has three layers 60, 62, and 62 of electrical insulation material, with the layers 60 and 64 being outer layers that define opposite faces 66 and 68 of the sheet 52 and the layer 62 being an inner or “core” layer sandwiched between the layers 60 and 64 and having a color selected to differentiate the layer 62 from the layers 60 and 64. As best seen in FIG. 4, the color of the core layer 62 allows the layer 62 to function as an end-of-life indicator for the isolation tool 50, with the exposure of the color of core layer 62 through either of the faces 66 and 68 indicating that at least one of the layers 60 and 64 has been worn away and/or damaged, as shown at 65 in FIG. 4, to the point that the tool 50 should be discarded and replaced with a new tool 50. For example, in the illustrated embodiment, the outer layers 60 and 64 can have an orange color and the core layer 62 can have a yellow color that can be seen when there is sufficient wear or damage to one of the outer layers 60 and 64, again as shown at 65 in FIG. 4.

Any suitable electrical insulation material can be used for each of the layers 60, 62, and 64. In the illustrated embodiment, each of the layers 60, 62, and 64 is made from the same insulation material, ethylene propylene diene Monomer (M-class) rubber (EPDM rubber), and can be formed as a single piece, multilayered component using a suitable calendering process.

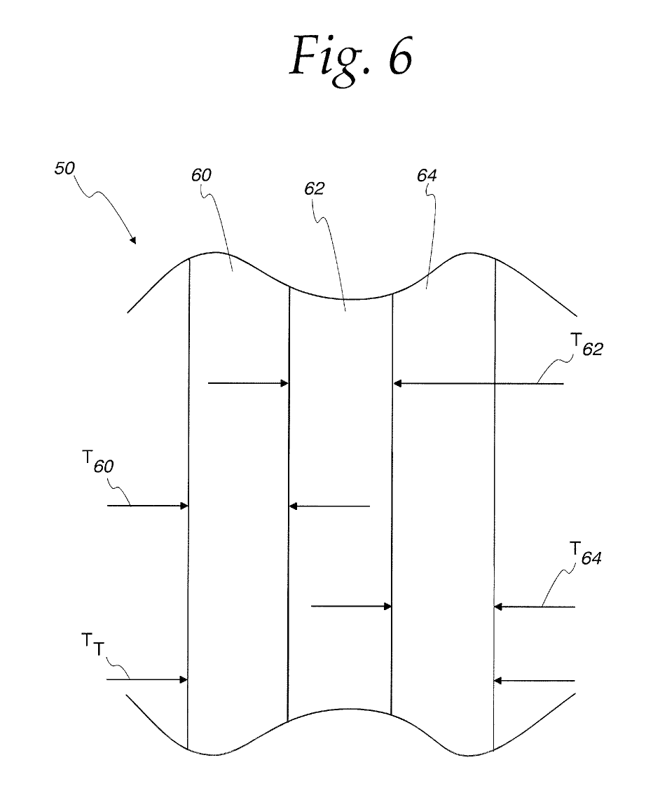

As best seen in FIG. 6, the sheet 52 has a total thickness T_{T}, with each of the layers 60, 62, and 64 having a thickness Tᵢ, with the thicknesses Tᵢ being equal in the illustrated embodiment. In one embodiment based on the illustrated embodiment, the sheet 52 has a total thickness of 0.150 inch, with each of the thicknesses Tᵢ being 0.050 inch, which enables the sheet 52 to withstand a 35,000 volt differential across the thickness T_{T} when the layers 60, 62, and 64 are made of EPDM rubber having a 50 durometer. In many embodiments, the sheet 52 can have a thickness T_{T} that is less than the illustrated embodiment but that would withstand a 1,000 volt differential across the thickness T_{T} when the layers 60, 62 and 64 are made of EPDM rubber having a 50 durometer. While the thicknesses Tᵢ are shown as being equal, it should be understood that in some applications it may be desirable for the thicknesses Tᵢ to be unequal, varying from one layer 60, 62, 64 to the next.

As best seen in FIG. 4, in the illustrated embodiment, the sheet 52 is rectangular with a pair of long sides 70 and a pair of short sides 72, with some embodiments of the sheet having sides 70 and 72 with lengths L₁ and L₂, respectively, in the range of 5 inches to 10 inches, and with one embodiment of the invention having sides 70 that are 7 inches in length (L₁=7″) and short sides 72 that are 6 inches in length (L₂=6″) which has proven to be a convenient and compatible size for many conventional enclosures 10.

Given the inherent symmetry of the illustrated embodiment of the tool 50 and sheet 52, it should be understood that any of the four end portions associated with the four sides 70, 70, 72, 72 of the rectangular sheet 52 could serve as a grip portion 55, with the opposite end portion of the sheet 52 serving as the insulation portion 57, and that the particular end portion of the sheet 52 used for the grip portion 55 and/or the insulation portion 57 can be varied as the tool 50 is repeatedly used with different enclosures 10. Thus, for the illustrated sheet 52, the grip portion 55 and the insulation portion 57 are interchangeable. It should further be understood that it is possible for the sheet 52 to be provided in shapes other than rectangular that would still allow for the grip portion 55 and/or the insulation portion 57 to be varied as the tool 50 is repeatedly used with different enclosures 10, such that the grip portion 55 and the insulation portion 57 could be interchangeable.

To install the tool 50, a user selects one of the end portions of the sheet 52 to be a grip portion 55 and grasps the selected grip portion 55 with a hand while inserting the opposite end portion, now serving as the insulation portion 57, into the gap or space between a pair 34 of terminals 30, 32 and a lateral side wall 24 and/or meter mount flange 26 of an enclosure 10, with the user deforming the sheet 52 as required to conform the sheet 52 to the available space. The user can then perform a service operation in the enclosure. To remove the tool 52, a user simple grasps the grip portion 55 and pulls the tool 52 from the enclosure 10.

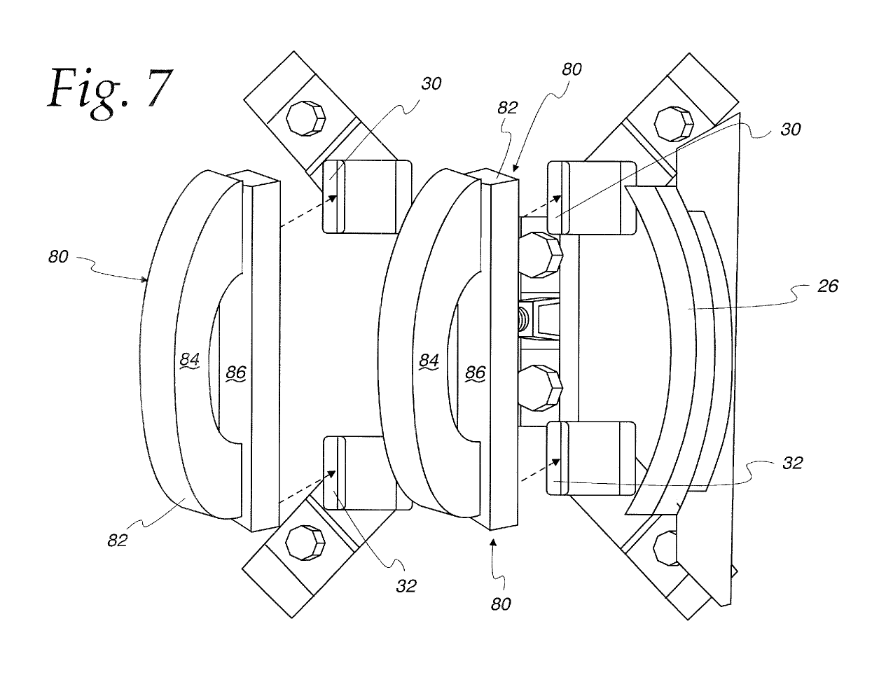

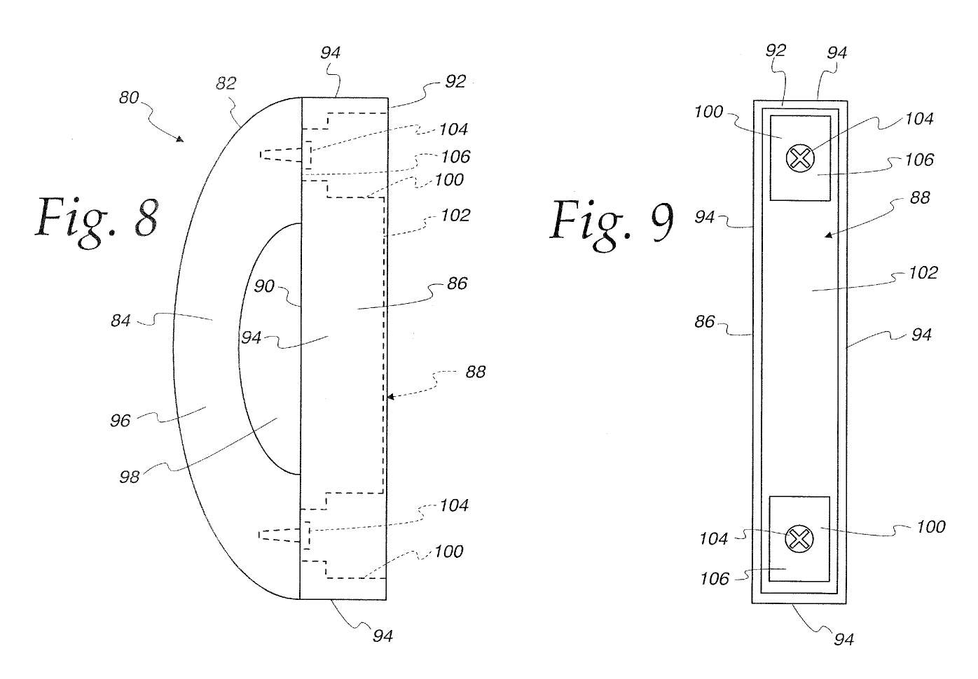

FIGS. 7-9 illustrate another embodiment for an isolation tool 80 having a one-piece, unitary component 82 including a grip portion 84 and an insulation portion 86. As best seen in FIGS. 8 and 9, the isolation tool 80 also includes an additional component in the form of an electrical shorting conductor 88 that is carried in the insulation portion 86. In the illustrated embodiment, the insulation portion 86 is defined by a planar upper surface 90, a planar lower surface 92, and four planar side surfaces 94 that extend from the upper surface 90 to the lower surface 92. The grip portion 84 is illustrated in the form of a curved handle 96 that extends upwards from the upper surface 90 to define a finger receiving opening 98 between the handle 96 and the upper surface 90. The electrical shorting conductor 88 is a one-piece, unitary component and includes two spaced sockets 100 connected by a flat, planar conduit portion 102 that extends from one socket 100 to the other socket 100. Each socket 100 is configured to receive a corresponding one of the terminals 30 and 32 in the enclosure 10, with each socket 100 and corresponding terminal 30, 32 forming a suitable electrical contact and having sufficient frictional engagement to maintain the terminal 30, 32 in the socket 100. The spacing between the sockets 100 is selected to conform to the spacing between the terminals 30 and 32 in the enclosure 10. In the illustrated embodiment, the lower surface 92 of the insulation portion 86 is relieved to conformingly receive the sockets 100 and portion 102 so that no lateral edge or side surface of the conductor 88 is exposed with the conductor 88 mounted in the insulation portion 86. In the illustrated embodiment, threaded fasteners 104 of any suitable form extend through a bottom surface 106 in each socket 100 to fix the conductor 88 to the insulation portion 86. It should be appreciated that the shape of the sockets 100 in the figures is for purposes of illustration and that the specific shape of each socket 100 will be highly dependent upon the specific shape of the mating terminal 30,32 for any particular application and enclosure 10 and that no limitation to the specific shape shown is intended unless expressly recited in a claim.

The conductor 88 allows the tool 80 to provide an additional function beyond the isolation function of the tool 50. Specifically, the conductor 88 provides shorting of the terminals 30 and 32, which as discussed in the Background Section of this disclosure is often desirable during installation and/or servicing of the enclosure 10. In this regard, it is contemplated that one or more (typically two) of the tools 80 could be provided with each of the enclosures 10 when the enclosures 10 are purchased by an installer so as to provide the installer with a simple and safe method of shorting the terminals 30 and 32 together. The tool(s) 80 can easily be removed by the installer when shorting of the terminals 30 and 32 is no longer desired, or the tool(s) can be left in place by the installer and then removed by the utility when the meter 12 is being installed in the enclosure 10.

To install the tool 80, a user simply grasps the grip portion 84 in a hand and pushes the tool onto a pair 34 of terminals 30 and 32 in an enclosure 10, with the sockets 100 frictionally engaged and making electrical contact with the terminals 30 and 32. The user can then perform a service operation in the enclosure. The tool 80 can be removed by a user by simply grasping the grip portion 84 in a hand and pulling the tool from the enclosure 10, thereby disengaging the sockets 100 from the terminals 30 and 32.

It should be understood that while specific forms and constructions of the tools 50 and 80 have been illustrated herein, other forms and constructions are possible within the scope of this disclosure and that no limitation is intended unless recited in an appended claim. For example, while the tool 50 is shown as a rectangular sheet that is planar in its uninstalled condition, other shapes are possible for the tool 50. Similarly, while the tool 80 is shown with curved handle 96 and a rectangular shaped insulation portion 86, other shapes are possible for the tool 80. As a further example, while the sheet 52 defining the tool 50 is shown as having three layers 60, 62, and 64 of electrical insulation material, it is possible for the sheet 52 to have less than three layers, only one layer, or more than three layers of electrical insulation material.

1. A method of electrically isolating a pair of spaced electric terminals in an electric distribution meter enclosure, the enclosure being electrically grounded, one of the terminals being connected to a power supply conduit from a utility, and the other of the terminals being connected to a customer supply conduit, the method comprising the steps of:
gripping a portion of an isolation tool with a user's hand;
inserting a portion of the isolation tool into an installed position between the enclosure and the terminals while performing the gripping step;
performing a service operation within the enclosure while the isolation tool is in the installed position; and
gripping a portion of the isolation tool with a user's hand after the performing step and removing the isolation tool from the installed position.

2. The method of claim 1 wherein the first recited gripping step comprises gripping a planar portion of a sheet defining the isolation tool, and the inserting step comprises deforming a planar portion of the sheet defining the isolation tool.

3. The method of claim 1 wherein the inserting step comprises engaging an electrical conduit member of the isolation tool with each of the terminals.

4. A method of electrically isolating pairs of spaced electric terminals in electric distribution meter enclosures, each of the enclosures being electrically grounded, one of the terminals of each pair being connected to a power supply conduit from a utility, and the other of the terminals of each pair being connected to a customer supply conduit, the method comprising the steps of:
gripping a portion of an isolation tool with a user's hand;
inserting a portion of the isolation tool into an installed position between an electric distribution meter enclosure and a pair of terminals while the performing the gripping step;
performing a service operation within the enclosure while the isolation tool is in the installed position;
removing the isolation tool from the installed position after the performing step; and
repeating the gripping, inserting, performing steps on a plurality of enclosures using the same isolation tool.

5. The method of claim 4 wherein the first recited gripping step comprises gripping a planar portion of a sheet defining the isolation tool and the inserting step comprises deforming a planar portion of the sheet defining the isolation tool.

6. The method of claim 4 wherein the inserting step comprises engaging an electrical conduit member of the isolation tool with each of the terminals.

7. An electrical isolation tool for isolating a pair of spaced electric terminals in an electric distribution meter enclosure, the enclosure being electrically grounded, one of the terminals being connected to a power supply conduit from a utility, and the other of the terminals being connected to a customer supply conduit, the isolation tool comprising:
a one piece, unitary component comprising:
a grip portion adapted to be grasped by in a hand of a user for installation and removal of the isolation tool to and from said electric distribution meter enclosure; and
an electrical isolation portion sized to extend continuously between said enclosure and said pair terminals with the isolation tool in an installed condition, the grip portion and the isolation portion comprising at least one layer of electrical insulation material extending continuously between the portions.

8. The isolation tool of claim 7 wherein the at least one layer of electrical insulation material is a flexible, resilient sheet deformable between an uninstalled condition and an installed condition.

9. The isolation tool of claim 8 wherein the sheet is planar in the uninstalled condition.

10. The isolation tool of claim 9 wherein the sheet is deformed to fit between said enclosure and said pair of terminals and to be frictionally engaged with at least one of said enclosure and said pair of terminals with the tool in the installed condition.

11. The isolation tool of claim 8 wherein the at least one layer of electrical insulation material is at least three layers of electrical insulation material, with two of the at least three layers being outer layers defining opposite faces of the sheet and the third of the at least three layers being an indicator layer located between the other two of the at least three layers and having a color selected to differentiate the indicator layer from the other two of the at least three layers.

12. The isolation tool of claim 8 wherein the grip portion and the electrical isolation portion are interchangeable portions of the sheet.

13. The isolation tool of claim 8 wherein the sheet is rectangular in shape with sides having lengths in the range of 5 inches to 10 inches.

14. The isolation tool of claim 7 wherein the isolation portion is configured to withstand at least a 1,000 volt differential across the isolation portion.

15. The isolation tool of claim 7 further comprising an electrical shorting conductor carried in said isolation portion and configured to extend between and engage with said terminals, and wherein the grip portion comprises a handle extending from the isolation portion to be encircled by a user's hand.
